(19) United States
(12) Patent Application Publication
(10) Pub. No.: US 2013/0240695 A1
(43) Pub. Date: Sep. 19, 2013

(54) BULLET RETAINING CLIP ASSEMBLY

(71) Applicant: SWEI-YIN CHAUNG, KOKOMO, IN (US)

(72) Inventor: SWEI-YIN CHAUNG, KOKOMO, IN (US)

(73) Assignee: DELPHI TECHNOLOGIES, INC., TROY, MI (US)

(21) Appl. No.: 13/419,841

(22) Filed: Mar. 14, 2012

(51) Int. Cl. H05K 7/00; H05K 5/02

(52) U.S. Cl. 248/220.22; 174/51

(57) ABSTRACT

A retainer for affixing an electromechanical device to adjacent motor vehicle support structure includes an locating pin integrally molded of relative hard material as an integral feature of the electromechanical device case. The locating pin includes parallel side walls forming an axially directed channel bifurcated by a tapered guideway and at least one inwardly facing engagement surface. The retainer also includes a relatively soft bushing clip having resilient arms slip-fit within said channel straddling the tapered guideway to self-lock with said engagement surface. The clip arms extend outwardly of said locating pin side walls and form opposed, axially extending bushing surfaces operative to engage vehicle support structure.

### TECHNICAL FIELD

The present invention relates generally to apparatus for mounting electro-mechanical subassemblies in motor vehicles, and more specifically relates to apparatus for efficiently securing an electro-mechanical device in the passenger area of a motor vehicle, and more particularly still, relates to the mounting of devices requiring an operator interface in the instrument panel area of a motor vehicle.

### BACKGROUND OF THE INVENTION

Electro-mechanical devices enclosed within a discrete housing assembly are frequently employed in automotive applications. Such housing assemblies are typically formed of sheet metal panels interconnected by threaded fasteners. By way of example, audio system and navigation system devices are enclosed within a box-like case which is mounted within a host vehicle passenger cabin by threaded fasteners passing through openings in laterally extending mounting flanges affixed to a front plate and a rearwardly directed mounting bushing which is threadably affixed to a stud carried on the outer surface of the rear wall of a wraparound case housing panel. Typically, the shank of the stud extends outwardly through a hole disposed within a localized recess in the rear panel. The rear mounting bushing for current audio systems is typically attached by welding a threaded stud to the back wall of the wrap around and then the bushing is screwed on.

Another known stud design includes a threaded shank secured to the rear wall of the device case by a set nut and receiving a molded rubber, plastic or vinyl stud thereover.

With the molded plastic device housing, the mounting bushing can be molded as an integral part of the receiver box, eliminating two part numbers and the labor to install them. In application, the rearwardly directed stud registers with an opening in a vehicle structural support member.

### SUMMARY OF THE INVENTION

These and other features and advantages of this invention will become apparent upon reading the following specification, which, along with the drawings, describes preferred and alternative embodiments of the invention in detail.

The present invention is preferably includes construction of a case and front plate of the housing assembly wherein both elements of the case assembly are formed of a composite of relatively rigid polymer material and electrically conductive material operable to shield the audio components (such as the circuit board subassembly and the CD player subassembly) from electrical anomalies including radio frequency interference (RFI), electromagnetic interference (EMI), bulk current injection (BCI) and electrostatic discharge (ESD). The electrically conductive material comprises substantially continuous planer sheet portions applied to surfaces of or within polymer housing assembly wall portions as discrete elements, electrically conductive paint, foil or electrostatic or vacuum deposition applied material. Alternatively, the electrically conductive material comprises a wire mesh screen which has been cut and folded to net shape and inserted within a mold cavity whereby it is effectively insert molded within the polymer based material. Preferably, the wire screen is centered within the wall portions of the case and front plate whereby electrically insulating polymer material effectively covers the wire screen, both inside and out, to prevent inadvertent grounding of the housing assembly to interior or exterior structures. A small portion of the conductive screen can be exposed in or near the mounting stud to provide a ground path the host vehicle body.

In the present invention, a retainer assembly is provided for affixing the case of an electro-mechanical device to adjacent motor vehicle support structure. The retainer assembly includes an elongated bullet locating pin molded of relatively hard material as an integral feature of said electro-mechanical device case and extending outwardly of said case. The bullet locating pin includes opposed parallel side walls forming an axially directed channel bifurcated by a tapered guideway and one or more inwardly facing engagement surfaces and an elongated bushing clip molded of relatively soft material. The bushing clip forms cooperating resilient arms configured for a slip-fit within said bifurcated channel straddling said tapered guideway and terminating in cooperating catch features operative, upon installation within said bullet locating pin, to self-lock with the engagement surface(s). The bushing clip arms extend radially outwardly of said locating pin side walls to form opposed, axially extending bushing surfaces operative to engage vehicle support structure. This arrangement has the advantage of employing a low cost integrated bullet locating pin with a soft bushing interface.

### BRIEF DESCRIPTION OF THE DRAWINGS

The present invention will now be described, by way of example, with reference to the accompanying drawings, in which:

FIG. 1, is a rear-left perspective view of a one-piece injection molded housing case for an automotive audio system and the like illustrating an integral, one-piece mounting stud extending from a rear wall of the case;

FIG. 2, is a broken, exploded, cross-sectional view of a “bullet” type rear mounting retainer assembly suitable for use with a molded housing case such as illustrated in FIG. 1;

FIG. 3, is a broken, cross-sectional view of the bullet mounting retainer assembly of FIG. 2, in a partially assembled state;

FIG. 4, is a broken, cross-sectional view of the bullet mounting retainer assembly of FIG. 2, in a fully assembled state;

FIG. 4A, is a broken, perspective view of the cooperating self-engagement features of the bullet locating pin and hairpin bushing clip of FIG. 4, on an enlarged scale; and

FIG. 5, is a cross-sectional view of the fully assembled bullet retainer assembly taken along lines 5-5 of FIG. 4.

Although the drawings represent embodiments of the present invention, the drawings are not necessarily to scale and certain features may be exaggerated in order to illustrate and explain the present invention. The exemplification set forth herein illustrates an embodiment of the invention, in one form, and such exemplifications are not to be construed as limiting the scope of the invention in any manner.

### DESCRIPTION OF THE PREFERRED EMBODIMENT

The present invention represents an improvement of the device described and illustrated in U.S. Pat. No. 7,733,659 B2 entitled “LIGHTWEIGHT AUDIO SYSTEM FOR AUTOMOTIVE APPLICATIONS AND METHOD” to Chris R. Snider et al. and assigned to the common assignee of the present invention. The entire specification and drawings of U.S. Pat. No. 7,733,659 B2 are incorporated herein by reference.

The present invention can be beneficially applied in mounting many types electromechanical devices, particularly for affixing such devices to adjacent support structure in a motor vehicle. The present invention is of particular advantage in the mounting of so-called “infotainment” systems (ex. audio and navigation systems) and related electronic packages within the passenger cabin of a motor vehicle and will be described in connection therewith.

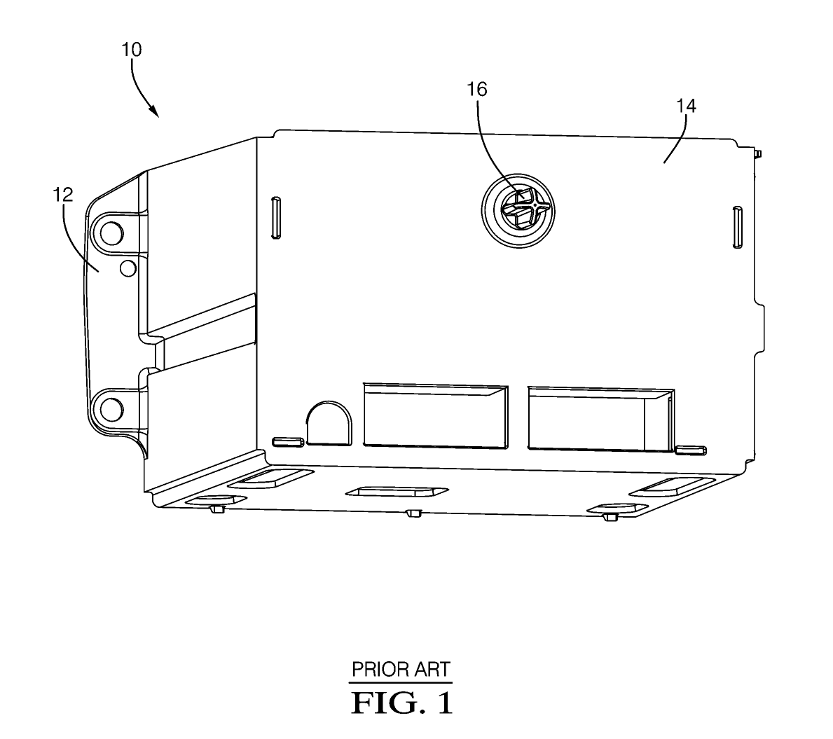

Referring to FIG. 1, a rear view of the case 10 of an audio system described in U.S. Pat. No. 7,733,659 B2 is depicted. Refer FIGS. 13, 14 and 91 of U.S. Pat. No. 7,733,659 B2. The case 10 is injection molded in a single structure of relatively rigid polymer based material, such as glass-filled polyester, glass-filled polypropylene, polycarbonate, PC/ABS and the like. Preferably, the case 10 is formed as a composite structure, with a preformed wire mesh insert molded therein operative to shield an electronic component mounted in the case 10 from electrical anomalies.

The case 10 has front mounting flanges 12 (one illustrated) for mounting the case 10 to a host vehicle instrument panel structure, and a rear wall 14 forming an integral rear mounting stud 16 extending outwardly therefrom. The stud 16 is elongated and has a characteristic cross or “+” shaped cross-section along its axial length. The cross-section configuration of the stud 16 has intersecting vertical and horizontal portions. The outwardmost surfaces of the vertical and horizontal portions are dimensioned to establish an interference fit within the opening of the host vehicle support member. Because the stud 16 is constructed of softer material (plastic) than the support member 198 (steel), the outer surfaces of the vertical and horizontal portions will tend to deform locally upon insertion into opening and thereby assure a tight connection. Rearwardly directed edges are configured with a sharp transition which will scarf the plastic material of the stud 16 upon any withdrawal from the opening.

The present invention provides improved, more robust retention of a rear case mount to the host vehicle support structure.

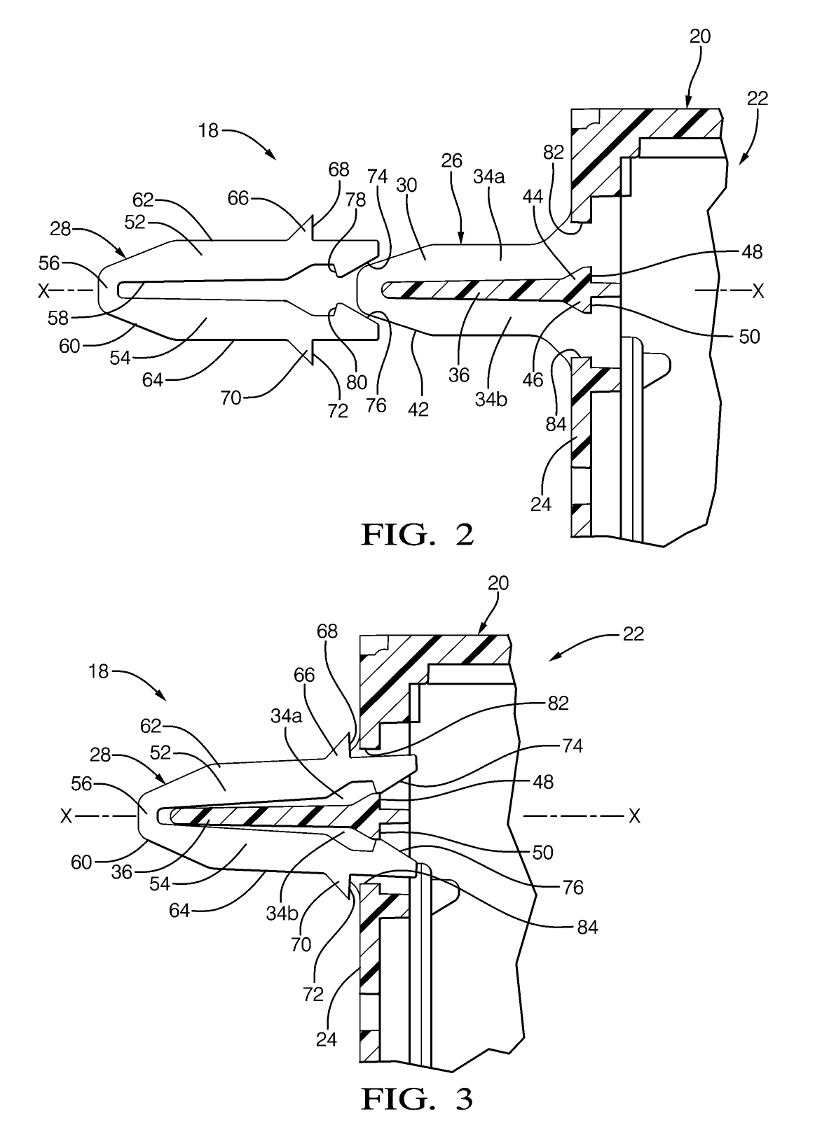

Referring to FIGS. 2-4, a retainer assembly 18, adapted for mounting a rear portion of the housing or case 20 of an electromechanical device 22, within a host motor vehicle, is illustrated. The retainer assembly 18 is affixed to and extends longitudinally rearwardly from the rear wall 24 of the case 20. The retainer assembly 18 includes a bullet locating pin 26 which is integrally formed (molded) with the case 20 and a separately formed hairpin bushing clip 28. The bullet locating pin 26 is formed of the same material as is the case 20 and is elongated along an axis designated X-X extending normally from the rear wall 24 of the case 20. Preferably, the case 20 and bullet locating pin 26 are integrally formed from 16% glass filled PC/ABS material. The hairpin bushing clip 28 is separately formed, such as being injection molded of a different material which is significantly softer than the material making up the case 20 and bullet locating pin 26. Preferably, the hairpin bushing clip 28 is formed of acetal plastic, such as Celcon M90-CA3208 presently sold by Ticona LLC. The acetal material is known commercially as POM and Celcon, inter alia., and has a lubricating property effectively eliminating potential squeak against the associated vehicle support structure.

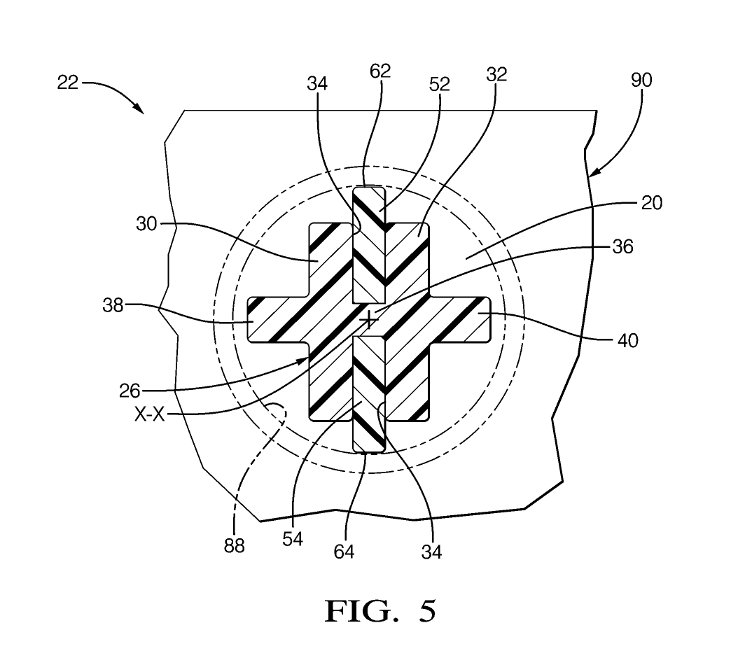

As best viewed in FIGS. 2 and 5, bullet locating pin 26 is elongated along axis X-X, and has a generally H-shaped cross-section. The bullet locating pin 26 has parallel left and right vertically extending side walls 30 and 32, respectively. The side walls 30 and 32 are laterally spaced apart to define a vertical aligned, axially directed channel 34. The channel 34 is vertically bifurcated by a tapered guideway 36 extending laterally between the side walls 30 and 32. Thus, tapered guideway 36 bisects the channel 34 into minor image upper and lower channel portions 34a and 34b, respectively. Left and right spacers 38 and 40 extend laterally from left and right side walls 30 and 32, respectively.

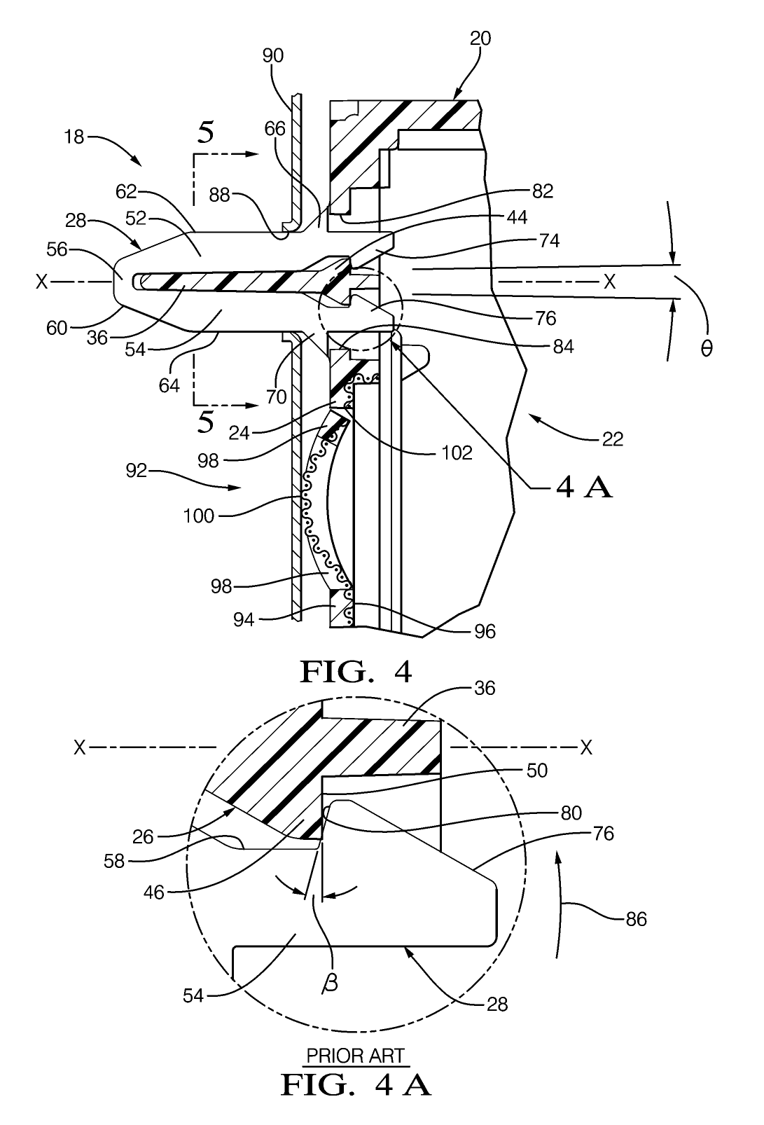

As best viewed in FIGS. 2 and 4, the left and right side walls 30 and 32 are generally “bullet shaped”, with a tapered or rounded leading edge 42 facing leftwardly away from the case 20. The tapered guideway 36 extends along axis X-X and is vertically tapered at a constant angle θ. The righthandmost portion of the tapered guideway 36 transitions into opposed upper and lower ramps 44 and 46 forming inwardly facing upper and lower engagement surfaces 48 and 50, respectively.

As best viewed in FIGS. 2, 4 and 5, the hairpin bushing clip 28 is shaped similarly to the side walls 30 and 32, having elongated upper and lower arms 52 and 54, respectively, joined at the lefthandmost end thereof by a web 56. The hairpin bushing clip 28 has a constant thickness enabling it to be slip-fit between side walls 30 and 32. The upper and lower arms 52 and 54 are vertically spaced by a tapered gap 58 at a constant angle θ. The hairpin bushing clip 28 is generally “bullet shaped”, with a tapered or rounded leading edge 60 facing leftwardly away from the case 20. The upper and lower horizontal surfaces of the arms 52 and 54 define substantially parallel, opposed upper and lower bushing surfaces 62 and 64, respectively. Adjacent the righthand portion thereof, the upper bushing surface 62 transitions into an upper ramp 66 forming an upper rightwardly facing stop surface 68. Likewise, adjacent the righthand portion thereof, the lower bushing surface 64 transitions into a lower ramp 70 forming a lower rightwardly facing stop surface 72.

Referring to FIGS. 2 and 4A, the righthandmost ends of arms 52 and 54 define cooperating inwardly directed upper and lower tapered guide surfaces 74 and 76, respectively forming a portion of the tapered gap 58. The tapered guide surfaces 74 and 76, at their respective apex, transition into generally leftwardly facing catch surfaces 78 and 80, respectively. Cooperating engagement surfaces 48 and 50 are offset from their respective catch surfaces by an acute angle β.

FIGS. 2-4 illustrate a sequential series of steps involving assembling the hairpin bushing clip 28 within the bullet locating pin 26.

Referring to FIG. 2, the hairpin bushing clip 28 is axially aligned with the bullet locating pin 26, and then displaced rightwardly with respect thereto. Insodoing, the upper and lower arms 52 and 54 of the hairpin bushing clip 28 register with and slidably engage the upper and lower channel portions 34a and 34b of the bullet locating pin 26. Simultaneously, the leading (lefthandmost) portion of the tapered guideway 36 penetrates the tapered gap 58.

Referring to FIG. 3, as the above described insertion continues, the tapered guide surfaces 74 and 76 of the hairpin bushing clip 28 will initially contact the upper and lower ramps 44 and 46 of the bullet locating pin 26, respectively. Upon further insertion, the ramping action will resiliently displace the leading end of the upper arm 52 upwardly and the leading end of the lower arm 54 downwardly. Simultaneously, the leading portions (righthandmost) of the arms 52 and 54 enter upper and lower openings 82 and 84 formed in the rear wall 24 of the case 20 adjacent the point of interconnection of the case 20 with the bullet locating pin 26.

FIG. 3 illustrates the condition wherein the respective apices of the respective bullet locating pin ramp surfaces 44 and 46 and hairpin bushing clip ramp surfaces 74 and 76 are in alignment. At this point, the free ends of the arms 52 and 54 are at their maximum deflection, with the arms 52 and 54 acting as resilient beams.

Referring to FIGS. 4 and 4A, assembly of the hairpin bushing clip 28 with the bullet locating pin 26 is completed when insertion is complete. At this point, the apices of the respective bullet locating pin ramp surfaces 44 and 46 pass slightly leftwardly beyond the hairpin bushing clip ramp surfaces 74 and 76. Insoding, the natural resiliency of the material forming the hairpin bushing clip 28 affects a snap catch or engagement whereby the engagement surfaces 48 and 50 of the bullet locating pin 26 are in an abuting relationship with the catch surfaces 78 and 80 of the hairpin bushing clip 28. Thus assembled, the hairpin bushing clip 28 cannot be withdrawn from its illustrated position without the use of a special removal tool applied inside the case 20 by a service technician.

Simultaneously with the above described snap-lock engagement of the hairpin bushing clip 28 with the bullet locating pin 26, the stop surfaces 68 and 72 formed by the outwardly directed ramps 66 and 70 engage the outer surface of the rear wall 24 of the case 20 to prevent further insertion of the hairpin bushing clip 28.

Referring to FIG. 4A, the mechanism of the interlocking engagement of the hairpin bushing clip 28 with the bullet locating pin 26 is illustrated. Preferably, the engagement surfaces 48 and 50 defined by the tapered guideway 36 of the bullet locating pin 26 extend nearly vertically. By contrast, the catch surfaces 78 and 80 of the hairpin bushing clip 28 are angularly offset by an acute angle β. This ensures robust line contact between the apex of the ramps 44 and 46 and the associated catch surfaces 78 and 80. In this condition, the arms 52 and 54 of the hairpin bushing clip 28 apply radial force, as indicated by arrow 86, as well as axially directed forces.

Referring to FIGS. 4 and 5, the electromechanical device is installed, for example, in a host motor vehicle. Insodoing, the retainer assembly is slip-fit or slightly interference fit through a flanged opening 88 formed in design intent support structure 90 to affect a rear mounting point. It is contemplated that two or more of such retainer assemblies can be employed in a single installation.

Referring to FIG. 5, the vertical dimension of the upper and lower arms 52 and 54 of the hairpin bushing clip 28 exceed that of the side walls 30 and 32 of the bullet locating pin 26. Thus, once installed, all loading between the electromechanical device 22 and the support structure 90 extends through the upper and lower bushing surfaces 62 and 64. The “+” shaped cross-section structure of the bullet locating pin 26 is dimensioned to provide locating spacer functionality while avoiding direct contact with the vehicle support structure 90, except for momentary high load or impact conditions.

It is to be understood that the invention has been described with reference to specific embodiments and variations to provide the features and advantages previously described and that the embodiments are susceptible of modification as will be apparent to those skilled in the art.

Furthermore, it is contemplated that many alternative, common inexpensive materials can be employed to construct the basis constituent components. Accordingly, the forgoing is not to be construed in a limiting sense.

The invention has been described in an illustrative manner, and it is to be understood that the terminology, which has been used is intended to be in the nature of words of description rather than of limitation. For example, the bushing surfaces formed by the bushing clip 28 are described in the preferred embodiment as being vertically separated. The bushing surfaces could also be horizontally separated or in other orientations without departing from the spirit of the present invention.

Obviously, many modifications and variations of the present invention are possible in light of the above teachings. For example, the bullet locating pin 26 can, alternatively, be fabricated separately from the case 20, but from the same or similar material, and subsequently affixed to the case 20. It is, therefore, to be understood that within the scope of the appended claims, wherein reference numerals are merely for illustrative purposes and convenience and are not in any way limiting, the invention, which is defined by the following claims as interpreted according to the principles of patent law, including the Doctrine of Equivalents, may be practiced otherwise than is specifically described.

1. A retainer assembly for affixing the case of an electro-mechanical device to adjacent motor vehicle support structure, said retainer assembly comprising:
an elongated bullet locating pin molded of relative hard material as an integral feature of said electro-mechanical device case and extending outwardly of said case, said bullet locating pin including opposed, spaced apart parallel side walls forming an axially directed channel bifurcated by a tapered guideway and at least one inwardly facing engagement surface; and
an elongated hairpin bushing clip molded of relatively soft material, said bushing clip forming cooperating resilient arms configured to be slip-fit within said bifurcated channel straddling said tapered guideway and terminating in cooperating catch features operative, upon installation. within said bullet locating pin, to self-lock with said at least one engagement surface, the bushing clip arms extending radially outwardly of said locating pin side walls and forming opposed, axially extending bushing surfaces operative to engage vehicle support structure,
wherein said hairpin bushing clip provides exclusive intermediate support between said case and said adjacent motor vehicle support structure.

2. The retainer assembly of claim 1, wherein said hairpin bushing clip arms are radially separated by a tapered space.

3. The retainer assembly of claim 2, wherein said bullet locating pin tapered guideway and hairpin bushing clip tapered arm spaces are cooperatively offset to affect surface to surface contact between the tapered arm and the clip arms when fully installed.

4. The retainer assembly of claim 1, wherein said elongated hairpin clip is formed of acetal plastic material.

5. The retainer assembly of claim 1, wherein said case and bullet locating pin are formed of PC/ABS glass filled material.

6. The retainer assembly of claim 1, wherein said bullet locating pin is integrally formed with a rear wall panel of said electro-mechanical device case and extends rearwardly therefrom.

7. The retainer assembly of claim 6, wherein said hairpin clip bushing surfaces are vertically disposed.

8. The retainer assembly of claim 6, wherein said hairpin clip bushing surfaces are horizontally disposed.

9. The retainer assembly of claim 1, further comprising opposite spacers outwardly extending from said side walls.

10. The retainer assembly of claim 1, wherein said hairpin clip bushing further comprises at least one axially inwardly facing stop surface configured, upon installation of said clip bushing within said bullet locating pin, to abut an outer surface of said case.

11. The retainer assembly of claim 1, wherein said at least one engagement surface comprises an opposed pair of engagement surfaces integrally formed with said tapered guideway.

12. The retainer assembly of claim 1, wherein said case is configured to enclose a motor vehicle electro-mechanical device.

13. The retainer assembly of claim 1, wherein said case is formed of a composite of pre-formed electrical conductive wire mesh inset molded within the hard polymer material.

14. The retainer assembly of claim 13, wherein said case has a portion of said conductive wire mesh expanded adjacent said bullet locating pin to establish an electrical ground with said vehicle support structure.

15. The retainer assembly of claim 1, wherein said hairpin bushing clip cooperating catch features define a catch surface extending at an oblique angle with respect to said bullet pin inwardly facing engaged surface to, upon installation of the hairpin bushing clip, affect line engagement at the point of contact therebetween.

16. A retainer assembly adapted for affixing the case of an electro-mechanical device to a host motor vehicle, said retainer assembly comprising:
a bullet locating pin integrally molded on an outer surface of said case; and
a hairpin bushing clip molded of relatively soft material affixed to said bullet locating pin to affect a guide bushing between said bullet locating pin and associated vehicle support structure,
wherein said hairpin bushing clip provides exclusive intermediate support between said case and said adjacent motor vehicle support structure.
